(19) United States
(12) Patent Application Publication
(10) Pub. No.: US 2021/0005830 A1
(43) Pub. Date: Jan. 7, 2021

(54) RELIABILITY OF MIXED-HETEROJUNCTION ORGANIC PHOTOVOLTAICS GROWN VIA ORGANIC VAPOR PHASE DEPOSITION

(71) Applicant: The Regents of the University of Michigan, Ann Arbor, MI (US)

(72) Inventors: Stephen R. FORREST, Ann Arbor, MI (US); Byeongseop SONG, Albuquerque, NM (US)

(73) Assignee: The Regents of the University of Michigan, Ann Arbor, MI (US)

(21) Appl. No.: 16/946,694

(22) Filed: Jul. 1, 2020

Related U.S. Application Data
(60) Provisional application No. 62/869,363, filed on Jul. 1, 2019.

(51) Int. Cl. H01L 51/42; H01L 51/00; H01L 51/44

(52) U.S. Cl. CPC H01L 51/424; H01L 51/44; H01L 51/0046; H01L 51/0013

(57) ABSTRACT

Provided herein is an organic photovoltaic device comprising one or ore layers comprising one or more organic and/or organometallic compounds, and one or more of these layers may have a root-mean-square surface roughness ranging from about 2 nm to about 10 nm. Additionally provided is a method of manufacturing an organic photovoltaic device, and may comprise depositing one or more organic and/or organometallic compounds in one or more layers having a root-mean-square surface roughness ranging from about 2 nm to about 10 nm. Also provided is an organic photovoltaic device comprises one or more layers of one or more organic and/or organometallic compounds, the layers are deposited by organic vapor phase deposition, and the PCE may decrease by no more than about 1% after 250 hours of illumination at 1 sun intensity.

This application claims the benefit of priority of U.S. Provisional Patent Application No. 62/869,363 filed on Jul. 1, 2019 the contents of which are incorporated herein by reference in their entirety.

This invention was made with government support under DE-EE0005310 awarded by the U.S. Dept. of Energy. The government has certain rights in the invention.

The present disclosure is directed to organic photovoltaic devices with improved morphology and enhanced performance.

Organic photovoltaic devices (OPV) are devices which convert electromagnetic radiation into an electrical output using one or more organic and/or organometallic active compounds. These devices may comprise one or more active compounds capable of absorbing electromagnetic radiation, one or more blocking layers, buffer layers, surface modification layers, and/or conducting or semiconducting layers such as silver (Ag) or indium-tin-oxide (ITO). Mixed-heterojunction solar cells typically comprise an active layer comprising one or more electron-donating materials and one or more electron-accepting materials with some degree of intermixing. Performance properties of OPVs such as power conversion efficiency (PCE), open circuit voltage (V_{OC}), fill factor (FF), short circuit current (J_{SC}), device stability, and device lifetime may be impacted by the morphology of various layers such as, for example, an active layer, a blocking layer, and/or a surface modifying layer.

Performance of organic photovoltaic devices may depend on careful morphological control of organic thin films. Morphological control can impact many performance properties such as, for example, operational stability and power conversion efficiency. An organic layer and/or thin film may comprise one or more organic and/or organometallic constituents. The surface roughness, crystalline structure, crystallite size, degree of crystallinity, and crystallite orientation of one or more constituents as well as the relative mixing and interfacial structure between two or more constituents are all exemplary morphological aspects which may impact an organic photovoltaic device's performance.

The morphology of an organic layer may be influenced by different processing parameters. Such parameters may include, for example, deposition technique and thermal processing. Exemplary deposition techniques include vacuum thermal evaporation (VTE) and organic vapor deposition (OVPD). It has been found, for example, that deposition of one or more organic layers having a rough surface morphology may improve an organic photovoltaic device's performance.

In one aspect, the present disclosure is directed to an organic photovoltaic device comprising one or more layers comprising one or more organic and/or organometallic compounds, and one or more of these layers may have a root-mean-square surface roughness ranging from about 2 nm to about 10 nm. The layers may be deposited by organic vapor phase deposition, and the power conversion efficiency of the device may decrease by no more than about 1% after 250 hours of illumination at 1 sun intensity.

In some embodiments, an organic photovoltaic device comprises one or more layers comprising one or more organic and/or organometallic compounds, wherein these compounds are capable of absorbing electromagnetic radiation having a wavelength between about 400 nm and about 1200 nm.

Some embodiments of the present disclosure relate to a method of manufacturing an organic photovoltaic device. The method comprises depositing one or more organic and/or organometallic compounds in one or more layers, and one or more of these layers may have a root-mean-square surface roughness ranging from about 2 nm to about 10 nm. In certain embodiments, one or more of the layers are deposited by organic vapor phase deposition.

In addition, other embodiments are directed to an organic photovoltaic device comprising one or more layers of one or more organic and/or organometallic compounds deposited by organic vapor phase deposition wherein the power conversion efficiency of the device does not decrease by more than about 1% after 250 hours of illumination at 1 sun intensity.

### BRIEF DESCRIPTION OF DRAWING(S)

FIG. 1 depicts surface roughness of exemplary embodiments of DBP:C₇₀ films grown by VTE before (a) and after (b) aging, and OVPD before (c) and after (d) aging.

FIG. 2 depicts surface roughness and aging of exemplary embodiments of Bphen films deposited on a smooth VTE DBP:C₇₀ layer (a)-(d) and rough OVPD DBP:C₇₀ layer (e)-(h).

FIG. 3 depicts XRD measurements of exemplary embodiments of (a)(I) VTE and (a)(II) OVPD grown DBP:C₇₀ layers, and Bphen on (b)(I) VTE and (b)(II) OVPD grown DBP:C₇₀ layers after aging.

FIG. 4 depicts current density-voltage characteristics of exemplary embodiments (a) before and (b) after aging.

FIG. 5 depicts (a) dark current characteristics, and capacitance-voltage characteristics of (b) 60 nm VTE DBP:C₇₀, (c) 200 nm VTE DBP:C₇₀, and (d) 200 nm OVPD DBP:C₇₀ exemplary embodiments before and after aging.

FIG. 6 depicts (a) PCE, (b) Voc, (c) responsivity, and (d) FF of exemplary embodiments.

FIG. 7 depicts XRD data of exemplary embodiments.

FIG. 8 depicts performance characteristics of exemplary embodiments.

As mentioned above, performance properties of OPVs such as power conversion efficiency (PCE), open circuit voltage (V_{OC}), fill factor (FF), short circuit current (J_{SC}), device stability, and device lifetime may be impacted by the morphology of various layers such as, for example, an active layer, a blocking layer, and/or a surface modifying layer. Various processing techniques such as, for example, organic vapor phase deposition (OVPD) and vacuum thermal evaporation (VTE) may be used to modify or control the morphology of one or more layers in an OPV device. In some embodiments, it has been found that incorporation of one or more layers with root-mean-square (RMS) surface roughness ranging from about 2 nm to about 10 nm in OPV devices resulted improved performance properties. In some embodiments, the power conversion efficiency does not decrease by more than about 1% after 250 hours of illumination at 1 sun intensity.

Active materials in OPV devices comprise organic and/or organometallic materials capable of absorbing electromagnetic radiation. Such materials may absorb, for example, near-ultraviolet light, visible light, and/or near-infrared light. Active materials may be electron donating materials, electron accepting materials, and may comprise mixtures of one or more electron donating materials and one or more electron accepting materials. The active materials used in the present disclosure may not be particularly limited. Some exemplary active materials may include fullerenes, fullerene derivatives, aromatic molecules, conjugated molecules, dye molecules, thiophene containing molecules, C₆₀, C₆₀ derivatives, C₇₀, C₇₀ derivatives, tetraphenyldibenzoperiflathen, anthracene-type compounds, perylene-type compounds, phthalocyanine-type compounds, and/or tetracyanoquinodimethane-type compounds.

Blocking layers, buffer layers, and/or surface modifying layers may be used in an OPV device. Blocking layers, buffer layers, and/or surface modifying layers may be used to modify charge transport through an OPV device. Such layers may, for example, block excitors transport, modify electron transport, and/or modify hole transport. Some exemplary blocking layers, buffer layers, and/or surface modifying layers may include organic compounds, organometallic compounds, aromatic compounds, and/or conjugated compounds. Blocking layers, buffer layers, and/or surface modifying layers used in the present disclosure may not be particularly limited. In some embodiments, performance of an OPV device may be influenced by the morphology of one or more blocking layers, buffer layers, and/or surface modifying layers. Moreover, in some embodiments, the morphology of one or more blocking layers, buffer layers, and/or surface modifying layers may change during normal operation and/or aging of an OPV device, and this change in morphology may increase or decrease the OPV device's performance. In some embodiments, bathophenanthroline (Bphen) may be used. The wide energy gap Bphen may be used in organic light emitting diodes (OLEDs) and OPVs. Bphen has optical transparency and excitors blocking capability. Devices containing Bphen may, however, suffer from morphological instability potentially resulting from its low glass-transition temperature of 62° C. Morphological changes with time of bathophenanthroline (Bphen) used as a cathode buffer layer in OPVs may strongly impact device reliability, and these changes may be reduced when the underlying active region of the OPV is grown by OVPD as opposed to VTE. Surface roughness ranging from about 2 nm to about 10 nm and/or a nanocrystalline morphology of one or more active layers may reduce morphological changes in one or more blocking layers, buffer layers, and/or surface modifying layers. Reducing morphological changes in one or more blocking layers, buffer layers, and/or surface modifying layers may result in improved device performance such as, for example, increase device lifetime, increase operational stability, and/or increase powerconversion efficiency.

The morphology of an organic and/or organometallic comprising layer may impact the performance of an OPV device. Organic and/or organometallic compounds may tend to crystalize, and controlling a degree of crystallinity, crystallite size, and crystallite orientation may impact device performance. In mixed-heterojunction OPVs, the degree of intermixing and nature of interfacial surfaces within a mixed-heterojunction may additionally impact device performance. Imparting one or more layers with a rough surface may result in improved device performance such as, for example, improved device stability and power conversion efficiency.

Degree of surface roughness may be measured by a variety of techniques such as, for example, atomic force microscopy (AFM) and may be reported as a root-mean-square (RMS) surface roughness. The root-mean-square surface roughness of one or more layers may be controlled over a range of values such as, for example, about 2 nm to about 10 nm, about 2 nm to about 8 nm, about 2 nm to about 6 nm, and/or about 3 nm to about 5 nm. In certain embodiments, the root-mean-square surface roughness is about 4 nm.

Various processing techniques may be used to impart one or more layers with a desired surface roughness. An active layer with an RMS surface roughness ranging from about 2 nm to about 10 nm may be deposited using organic vapor phase deposition. Surface roughness of a previously deposited layer may impart surface roughness on a subsequently deposited layer. Deposition of a buffer layer onto an active layer having an RMS surface roughness ranging from about 2 nm to about 10 nm may result in a buffer layer having a surface roughness greater than about 0.8 nm, greater than about 1 nm, and/or greater than about 1.2 nm. Imparting one or more layers with a nanocrystalline morphology may result in improved device performance such as, for example, improved device stability and power conversion efficiency. Deposition of an active layer by OVPD may result in increased crystallinity, a nanocrystalline morphology, and/or improved device properties such as, for example, improved device stability and power conversion efficiency. It was found that morphological transformations of Bphen deposited onto a tetraphenyldibenzoperiflathen (DBP):C₇₀ mixed active region grown by VTE resulted in an open-circuit voltage (V_{OC}) reduction from 0.91±0.01 V to 0.52±0.01 V after 250 hours under simulated AM 1.5 G solar illumination and a 50% decrease in power conversion efficiency from PCE=6.0±0.2% to 3.1±0.2%. Morphological degradation may also result in electrical shorts across devices. For example, the as-grown yield of VTE-grown devices was >90% and reduced to <70% after aging.

Various processing and/or deposition techniques may be employed to deposit one or more layers with a given morphology and/or modify the morphology of one or more layers. Each layer may contain one or more organic and/or organometallic compounds. Various techniques include, for example, vacuum thermal evaporation (VTE), organic vapor deposition (OVPD), solution processing, and/or thermal conditioning. By using inert carrier gas, OVPD may provide extra energy for organic molecules to find thermodynamic equilibrium as they adsorb onto a substrate. Contrastingly, thermally evaporated molecules in conventional vacuum thermal evaporation (VTE) growth may proceed ballistically until these molecules strike a substrate and these molecules may have little energy for reorientation. Accordingly, the morphologies achieved via OVPD may differ markedly from those obtained by VTE. OVPD may also result in improved material utilization efficiency, scalability, and lifetime relative to VTE. For example, DBP:C₇₀ active layers grown by OVPD may be significantly more crystalline and with rougher surfaces than blends grown using VTE. The rough surface of OVPD grown active layer devices was found to pin the morphology of a subsequent Bphen layer, and resulted in a longer device lifetime and higher yield compared with analogous VTE-grown devices. OVPD-grown active layer devices experienced little change in V_{OC} or PCE from an initial value of 6.7±0.2% after 250 hours of operation, and these devices maintained a yield of >90% throughout an aging process. OVPD may be used to deposit one or more layers comprising one or more organic and/or organometallic compounds. Additionally, OVPD may be used to co-deposit two or more organic and/or organometallic compounds in one or more layers.

One or more active layers may be deposited via OVPD and have an increased surface roughness and/or improved nanocrystalline morphology relative to active layers deposited by VTE. Devices constructed with one or more active layers having a rougher surface may demonstrate improved device performance relative to corresponding devices made using one or more smoother active layers. An effective way of reducing morphological degradation in a cathode buffer layer deposited on mixed heterojunction OPVs is presented. A Bphen buffer layer may have a strong tendency to crystallize, which can harm the lifetime of devices and may lead to a power conversion efficiency drop. For example, in VTE-grown devices the power conversion efficiency has been observed to dropped from PCE=6.0±0.2% to 3.1±0.2% during aging. Morphological degradation not only effects device performance, but may also electrically short thin-film devices and reduce device yields from >90% to <70%. By employing a rough surface of nanocrystalline active layer grown by organic vapor phase deposition (OVPD), the morphological change of Bphen may be hindered and stability of the power conversion efficiency may be improved. In exemplary OVPD-grown devices, a more stable power conversion efficiency is demonstrated with initial PCE 6.7±0.2% and >90% yield throughout an aging process.

Various devices made according to the foregoing disclosures were made and tested. The embodiments described herein are further illustrated by the following non-limiting examples.

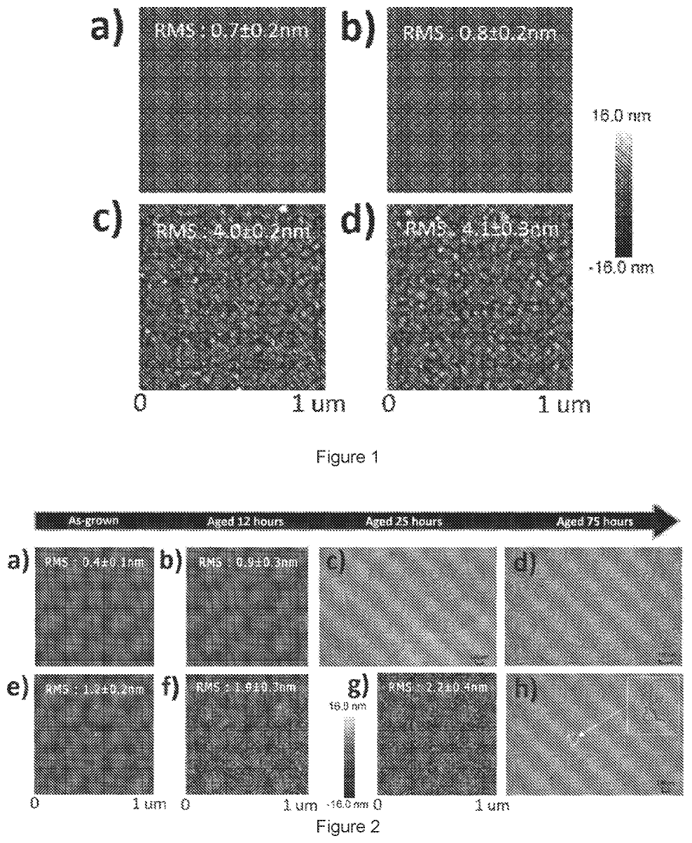

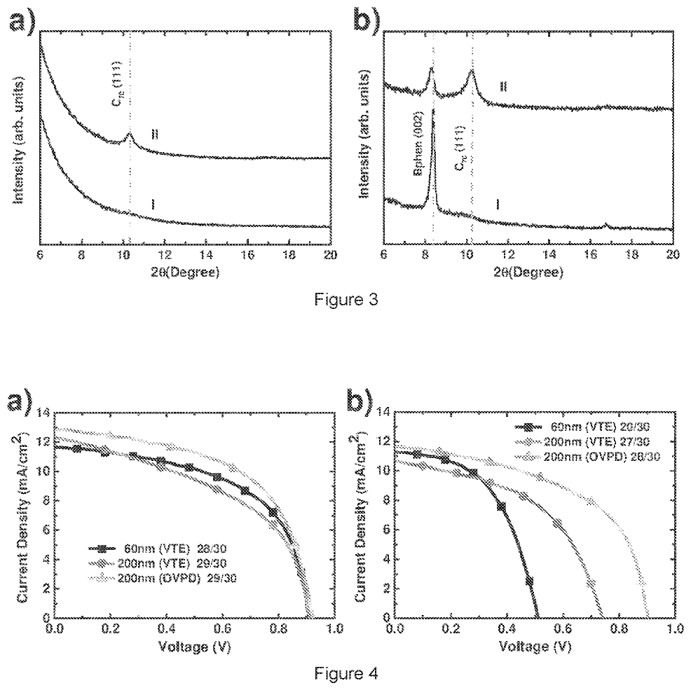

Mixed heterojunction composed of tetraphenyldibenzoperiflanthene (DBP) and C₇₀ was deposited by OVPD to form a rough surface with enhanced crystallinity. DBP:C₇₀ was co-evaporated at 375±2° C. and 520±2° C. inside a reactor having three temperature zones of 560° C., 500° C., 440° C. each. A deposition rate of 0.2 Å/s and 2.0 Å/s was achieved, and led to a 1:10 volume ratio. 10 sccm (standard cubic centimeters per minute) N₂ flow was used in each source barrel along with 6 sccm dilution flow directly through the chamber which resulted in a chamber pressure of 0.28 torr. The substrate was water-cooled to T_{S}=25° C. Atomic force microscopic (AFM) images of glass/indium tin oxide (ITO)/MoO₃ (10 nm)/DBP:C₇₀ (60 nm for VTE-grown, 200 nm for OVPD-grown, 1:10 volume each) were taken as-grown (FIG. 1a VTE, FIG. 1c OVPD) and after 75 hours (FIG. 1b VTE, FIG. 1d OVPD) under simulated AM 1.5 G illumination in ultra-high purity (H₂O, O₂<1 ppm) N₂ glove box. Exemplary VTE-grown active layers showed a much smoother surface compared to OVPD-grown layers, and a nanocrystalline morphology of C₇₀ in OVPD-grown layers was observed. AFM and optical microscope images of an exemplary 8 nm thick Bphen layer on a 1:10 by volume DBP:C₇₀ active layer with 60 nm thick for VTE-grown devices and 200 nm thick for OVPD-grown devices is shown in FIG. 2. FIGS. 2(a)-(d) and FIGS. 2(e)-(h) show images of exemplary Bphen grown by VTE and OVPD, respectively, after 0, 12, 25, and 75 hours of aging under simulated AM 1.5 G solar illumination. An initial Bphen surface had an RMS roughness of 0.4±0.1 nm, followed by spherulite growth appearing within 25 hours (FIGS. 2c and 2d). In contrast, Bphen grown on an exemplary rough nanocrystalline OVPD grown active layer with RMS=1.2±0.2 nm, FIG. 2(e), became only marginally rougher up to RMS=2.2±0.4 nm over this same time period (FIGS. 2(f)-(g)) and showed few regions of local crystallization after 75 hours (FIG. 2h). The active layer surface had a roughness of RMS=0.8±0.2 nm for VTE and 4.1±0.2 nm for OVPD both initially and after 75 hours. This may demonstrate that an initially rough surface pinned the morphology of Bphen compared to the smooth active layer grown by VTE. X-ray diffraction (XRD) measurements for exemplary 100 nm thick VTE and OVPD deposited DBP:C₇₀ layers on sapphire are shown in FIG. 3a. The peak at 10.26±0.03° corresponds to diffraction from the (111) plane of the face-centered-cubic (fcc) crystal structure of C₇₀ which is only apparent in an exemplary OVPD-grown layer (curve II). This may indicate a nano-crystalline morphology. The featureless diffraction from an exemplary VTE-grown active layer; however, may indicate a more amorphous structure (curve I). Following aging for 75 hours, XRD measurements of exemplary 50 nm Bphen on 100 nm DBP:C₇₀ on sapphire showed the emergence of a narrow and strong reflection at 8.37±0.03° corresponding to a planar spacing of d₀₀₂=10.55±0.04 Å of the orthorhombic Bphen crystal structure on the VTE-grown active layer (curve I, FIG. 3b). However, the peak from Bphen on the exemplary OVPD-grown layer was broad and weak (curve II). FIG. 7 summarizes the crystallographic data with (a) d-spacings calculated using the Bragg equation 2·d·sin(θ)=n·λ where θ is the Bragg angle and λ is the wavelength of Cu-kα; (b) calculated using the Scherrer equation t=(Kλ)/(B·cos(θ)) where K is the constant dependent on crystallite shape (0.9), A is the wavelength of Cu-kα line, B is the full width at half maximum value of the peak, and θ is the Bragg angle; (c) is calculated based on the (002) plane in the orthorhombic Bphen crystal structure; and (d) is calculated based on the (111) plane in the face-centered-cubic C₇₀ crystal structure. From the full width at half maximum value of each peak (FIG. 7), it was estimated that exemplary aged Bphen crystallite size was at least 35% smaller when grown on an OVPD active layer than on one grown by VTE. Since an exemplary Bphen thickness of 50 nm is much greater than it is typically used in an OPV (typically ˜8 nm), the actual differences of Bphen crystallite sizes might be larger in devices since the added thickness diminishes the effects of surface roughness on morphology.

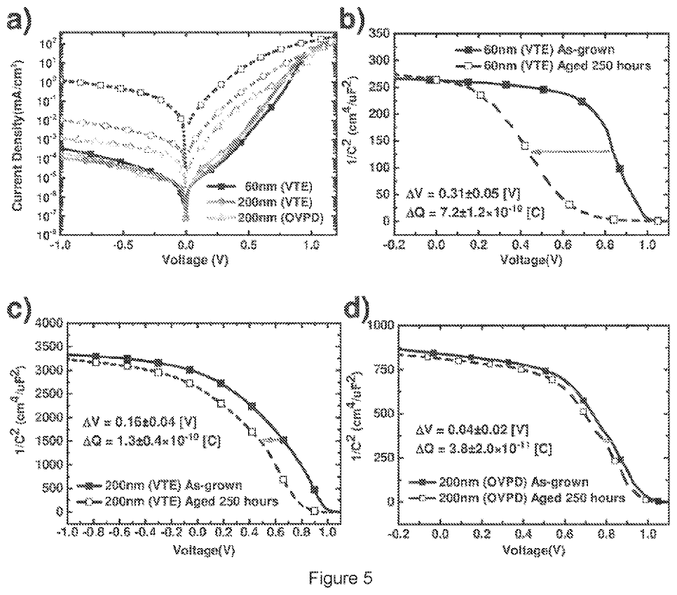

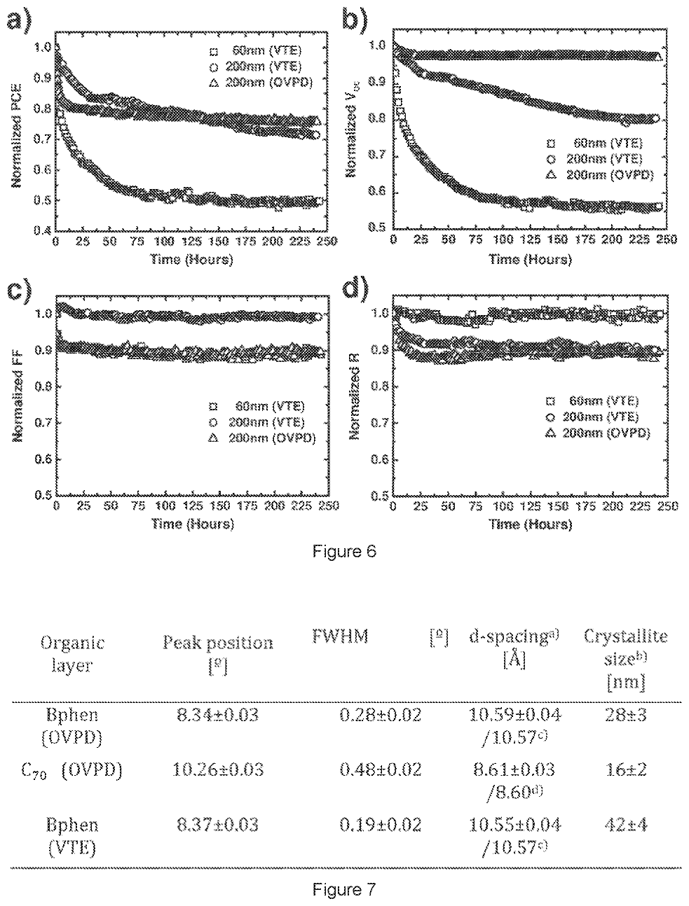

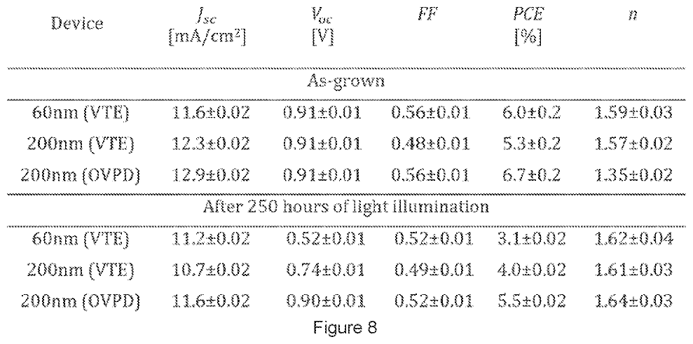

The deposition of one or more rough surfaces increased the operational lifetime of OPV cells. Three exemplary devices were fabricated with the following structures: Glass/ITO/DBP:C₇₀/Bphen (8 nm by VTE)/Ag (100 nm). Exemplary DBP:C₇₀ layers, at 1:10 volume ratio, had thicknesses of 60 nm (VTE), 200 nm (VTE), and 200 nm (OVPD). The exemplary OVPD-grown device had a higher fill factor (FF) compared to the VTE-grown device at the same thickness (200 nm), as shown in FIG. 4a and FIG. 8, which may be due to a low series-resistance arising from a C₇₀ nanocrystalline morphology in OVPD-grown active layers. After 250 hours of illumination at 1 sun intensity, an exemplary VTE-grown device exhibited a substantial drop in V_{OC} (FIG. 4b) which may be due to morphological degradation of the Bphen buffer. In addition, exemplary device yield for the 60 nm thick VTE-grown population decreased from 93% to 67% out of a total of 30 devices after 250 hours aging due to the formation of electrical shorts. This may be due to the Ag cathode penetrating the Bphen layer as crystallites form during aging. Thick (200 nm) exemplary devices grown by both VTE and OVPD showed only a few shorted devices during aging. The change in dark current in VTE and OVPD-grown devices is also shown in FIG. 5a. Among these three devices, the 200 nm OVPD-grown device had the least increase in dark current and maintained V_{OC} after aging. Capacitance-voltage (I/C²-V) characteristics are provided in FIG. 5b-5d. From the I/C²-V characteristics, a change in the amount of free carriers trapped at the interface between the active layer and Bphen before and after the aging period may be calculated. Accumulation of charge at the interface between the active layer and Bphen may reduce the effective potential barrier and lead to a drop in V_{OC}. The amount of charge trapped in these exemplary devices was calculated by taking the constant capacitance in the middle of low-forward bias region and was found to be ΔQ=7.2±1.2×10⁻¹⁰ [C] for a 60 nm VTE-grown active layer device, ΔQ=1.3±0.4×10⁻¹⁰ [C] for a 200 nm VTE-grown device, and ΔQ=3.8±2.0×10⁻¹¹ [C] for a 200 nm OVPD-grown device. These large amounts of trapped charge relative to a 200 nm OVPD-grown device led to decreased built-in voltages of 0.31±0.05 [V] and 0.16±0.04 [V] for the 60 nm and 200 nm VTE grown devices respectively. From the overall lifetime characteristic of these devices (FIG. 6), it was observed that the decrease in V_{OC} resulted in decreased PCE for both VTE-grown devices. For the 200 nm thick OVPD-grown device, both responsivity and FF decreased by about 10% during the first 25 hours of aging (FIG. 1e, FIG. 1f, and FIG. 1g). However, overall device performance maintained after this transition period suggesting a more stabilized Bphen morphology.

What is claimed is:

1. An organic photovoltaic device comprising one or more layers comprising one or more organic and/or organometallic compounds, wherein one or more of these layers have a root-mean-square surface roughness ranging from about 2 nm to about 10 nm.

2. The organic photovoltaic device according to claim 1, wherein one or more of the layers are deposited by organic vapor phase deposition.

3. The organic photovoltaic device according to claim 1, wherein one or more of the layers has a nanocrystalline morphology.

4. The organic photovoltaic device according to claim 1, wherein the organic photovoltaic device is a mixed-heterojunction organic photovoltaic device.

5. The organic photovoltaic device according to claim 1, wherein the power conversion efficiency does not decrease by more than about 1% after 250 hours of illumination at 1 sun intensity.

6. The organic photovoltaic device according to claim 2, wherein one or more of the layers deposited by organic vapor phase deposition comprise a fullerene and/or fullerene derivative.

7. The organic photovoltaic device according to claim 2, wherein one or more of the layers deposited by organic vapor phase deposition comprise two or more organic and/or organometallic compounds.

8. The organic photovoltaic device according to claim 2, wherein one or more of these layers have a root-mean-square surface roughness ranging from about 3 nm to about 5 nm.

9. A method of manufacturing an organic photovoltaic device comprising depositing one or more organic and/or organometallic compounds in one or more layers having a root-mean-square surface roughness ranging from about 2 nm to about 10 nm.

10. The method according to claim 9, wherein one or ore of the layers are deposited by organic vapor phase deposition.

11. The method according to claim 9, wherein one or more of the layers have a nanocrystalline morphology.

12. The method according to claim 9, wherein the organic photovoltaic device is a mixed-heterojunction organic photovoltaic device.

13. The method according to claim 9, wherein the root-mean-square surface roughness of the one or more layers having a root-mean-square surface roughness ranging from about 2 nm to about 10 nm does not change by more than about 5% after 75 hours of AM 1.5 G solar illumination in an essentially oxygen and moisture free environment.

14. The method according to claim 10, wherein one or more of the layers deposited by organic vapor phase deposition comprise a fullerene and/or fullerene derivative.

15. The method according to claim 10, wherein one or more of the layers deposited by organic vapor phase deposition comprise two or more organic and/or organometallic compounds.

16. An organic photovoltaic device comprising one or more layers of one or more organic and/or organometallic compounds deposited by organic vapor phase deposition wherein the power conversion efficiency of the device does not decrease by more than about 1% after 250 hours of illumination at 1 sun intensity.

17. The organic photovoltaic device according to claim 16, wherein one or more of the layers has a nanocrystalline morphology.

18. The organic photovoltaic device according to claim 16, wherein one or more of the layers deposited by organic vapor phase deposition comprise a fullerene and/or fullerene derivative.

19. The organic photovoltaic device according to claim 16, wherein one or more of the layers deposited by organic vapor phase deposition comprise two or more organic and/or organometallic compounds.
